(19) United States
(12) Patent Application Publication
(10) Pub. No.: US 2025/0247950 A1
(43) Pub. Date: Jul. 31, 2025

(54) WIRING MODULE AND METHOD OF MANUFACTURING WIRING MODULE

(71) Applicant: SUMITOMO ELECTRIC INDUSTRIES, LTD., Osaka (JP)

(72) Inventors: Shun ENDO, Osaka (JP); Masaki SUZUKI, Osaka (JP); Takeshi INOUE, Osaka (JP)

(73) Assignee: SUMITOMO ELECTRIC INDUSTRIES, LTD., Osaka (JP)

(21) Appl. No.: 19/007,845

(22) Filed: Jan. 2, 2025

(30) Foreign Application Priority Data
Jan. 26, 2024 (JP) 2024-010139

(51) Int. Cl. H05K 1/02; G01R 31/317; H05K 3/30

(52) U.S. Cl. CPC H05K 1/0248; G01R 31/31725; H05K 1/0243; H05K 3/303; H05K 2201/10356; H05K 2201/10522

(57) ABSTRACT

A wiring module includes a substrate, and a first wiring portion and a second wiring portion respectively transmitting a first signal and a second signal constituting a differential signal. Each of the first wiring portion and the second wiring portion includes a first wiring provided on the substrate, a second wiring provided on the substrate, and a skew adjustment element mounted on the substrate and including a third wiring. The third wiring has a first end conductively bonded to the first wiring and a second end conductively bonded to the second wiring. In at least one of the first wiring portion or the second wiring portion, the skew adjustment element further includes a dielectric, and the third wiring is provided on a surface of the dielectric except for a region facing the substrate.

### CROSS REFERENCE TO RELATED APPLICATIONS

This application claims priority based on Japanese Patent Application No. 2024-010139 filed on Jan. 26, 2024, and the entire contents of the Japanese patent application are incorporated herein by reference.

### TECHNICAL FIELD

The present disclosure relates to a wiring module and a method of manufacturing the wiring module.

### BACKGROUND ART

Patent literature (Japanese Unexamined Patent Application Publication No. 2015-185325) discloses a technique related to a cable harness and a method of manufacturing the cable harness. The cable harness includes a plurality of electric wires. The plurality of electric wires are electrically connected to a connection member at both ends. Every two wires are paired, and the difference in propagation delay time of signals in each pair of wires is 10 ps/m or less. The plurality of electric wires are connected to the connection member in a state where positions of end portions of the plurality of electric wires in the length direction are aligned. The connection member is provided with a circuit portion connected to the plurality of electric wires. The circuit portion includes a terminal for connection to an external device. At least one of the plurality of electric wires has a bending portion.

### SUMMARY OF THE INVENTION

A wiring module according to an aspect of the present disclosure includes a substrate, and a first wiring portion and a second wiring portion respectively transmitting a first signal and a second signal constituting a differential signal. Each of the first wiring portion and the second wiring portion includes a first wiring provided on the substrate, a second wiring provided on the substrate, and a skew adjustment element mounted on the substrate and including a third wiring. The third wiring has a first end conductively bonded to the first wiring and a second end conductively bonded to the second wiring. In at least one of the first wiring portion or the second wiring portion, the skew adjustment element further includes a dielectric, and the third wiring is provided on a surface of the dielectric except for a region facing the substrate. A first length from the first end to the second end of the third wiring of the skew adjustment element in the first wiring portion is different from a second length from the first end to the second end of the third wiring of the skew adjustment element in the second wiring portion.

### BRIEF DESCRIPTION OF THE DRAWINGS

FIG. 1 is a perspective view showing a wiring module.

FIG. 2 is a cross-sectional view taken along line II-II shown in FIG. 1.

FIG. 3 is a cross-sectional view taken along line III-III shown in FIG. 1.

FIG. 4 is a flow chart showing a method of manufacturing a wiring module.

FIGS. 5A, 5B and 5C are perspective views showing examples of a plurality of skew adjustment elements having different lengths of third wirings.

FIGS. 6A, 6B and 6C are side views showing examples of a plurality of skew adjustment elements having different dielectric constants of dielectrics.

### DETAILED DESCRIPTION

In high-speed communication, for example, a differential signal is transmitted using two signal wires. At this time, a skew occurs in the differential signal due to a difference in length between the two signal wires that transmit the differential signal, the density of the resin that covers the two signal wires, and the like. When the skew of the differential signal increases, the accuracy of reception of the differential signal is impaired on the reception side.

An object of the present disclosure is to provide a wiring module capable of reducing a skew of a differential signal and a method of manufacturing the wiring module.

### Description of Embodiments of Present Disclosure

First, the contents of embodiments of the present disclosure will be listed and explained. [1] A wiring module according to an aspect of the present disclosure includes a substrate, and a first wiring portion and a second wiring portion respectively transmitting a first signal and a second signal constituting a differential signal. Each of the first wiring portion and the second wiring portion includes a first wiring provided on the substrate, a second wiring provided on the substrate, and a skew adjustment element mounted on the substrate and including a third wiring. The third wiring has a first end conductively bonded to the first wiring and a second end conductively bonded to the second wiring. In at least one of the first wiring portion or the second wiring portion, the skew adjustment element further includes a dielectric, and the third wiring is provided on a surface of the dielectric except for a region facing the substrate. A first length from the first end to the second end of the third wiring of the skew adjustment element in the first wiring portion is different from a second length from the first end to the second end of the third wiring of the skew adjustment element in the second wiring portion.

In the wiring module according to [1], the length of the third wiring of the skew adjustment element in the first wiring portion (first length) is different from the length of the third wiring of the skew adjustment element in the second wiring portion (second length). In this case, by selecting a combination of the first length and the second length, it is possible to make the skew between the first signal after being transmitted through the first wiring portion and the second signal after being transmitted through the second wiring portion smaller than the skew between the first signal before being transmitted through the first wiring portion and the second signal before being transmitted through the second wiring portion. Thus, according to the wiring module of the above [1], it is possible to reduce the skew of the differential signal.

[2] In the wiring module according to [1], the skew adjustment element in each of the first wiring portion and the second wiring portion may include the dielectric. The dielectric of the skew adjustment element in the first wiring portion may have a thickness different from a thickness of the dielectric of the skew adjustment element in the second wiring portion, and thereby the first length may be different from the second length. With such a configuration of the skew adjustment element, it is possible to realize an aspect in which the first length is different from the second length with a simple structure.

[3] A wiring module according to an embodiment of the present disclosure includes a substrate, and a first wiring portion and a second wiring portion respectively transmitting a first signal and a second signal constituting a differential signal. Each of the first wiring portion and the second wiring portion includes a first wiring provided on the substrate, a second wiring provided on the substrate, and a skew adjustment element mounted on the substrate and including a third wiring. The third wiring has a first end conductively bonded to the first wiring and a second end conductively bonded to the second wiring. In each of the first wiring portion and the second wiring portion, the skew adjustment element further includes a dielectric, and the third wiring is provided on a surface of the dielectric except for a region facing the substrate. A first dielectric constant of the dielectric of the skew adjustment element in the first wiring portion is different from a second dielectric constant of the dielectric of the skew adjustment element in the second wiring portion.

In the wiring module according to [3], a dielectric constant (first dielectric constant) of the dielectric of the skew adjustment element in the first wiring portion is different from a dielectric constant (second dielectric constant) of the dielectric of the skew adjustment element in the second wiring portion. The propagation speed of a signal transmitted through the third wiring varies depending on the dielectric constant of the dielectric adjacent to the third wiring. Thus, by selecting a combination of the first dielectric constant and the second dielectric constant, it is possible to make the skew between the first signal after being transmitted through the first wiring portion and the second signal after being transmitted through the second wiring portion smaller than the skew between the first signal before being transmitted through the first wiring portion and the second signal before being transmitted through the second wiring portion. Thus, according to the wiring module of the above [3], it is possible to reduce the skew of the differential signal.

[4] In the wiring module according to any one of [1] to [3], the dielectric of the skew adjustment element in each of the first wiring portion and the second wiring portion may include at least one of ceramic or glass epoxy. In this case, by making the composition of the ceramic or glass epoxy different between the skew adjustment element in the first wiring portion and the skew adjustment element in the second wiring portion, the dielectric constants of the dielectrics of the skew adjustment elements can be effectively made different from each other.

[5] In the wiring module according to [1] to [4], the third wiring of the skew adjustment element in each of the first wiring portion and the second wiring portion may include at least one metal of gold, silver, copper, tin, nickel, or chromium. In that case, the third wiring can be formed, for example by plating, which adheres strongly to the surface of the dielectric.

[6] A method of manufacturing a wiring module according to an embodiment of the present disclosure includes preparing a first wiring portion and a second wiring portion respectively transmitting a first signal and a second signal constituting a differential signal, each of the first wiring portion and the second wiring portion having a first wiring and a second wiring provided on a substrate; measuring a skew between the first signal and the second signal; and in each of the first wiring portion and the second wiring portion, mounting a skew adjustment element including a third wiring having a first end and a second end by disposing the skew adjustment element on the substrate and conductively bonding the first end and the second end respectively to the first wiring and the second wiring. In at least one of the first wiring portion or the second wiring portion, the skew adjustment element further includes a dielectric, and the third wiring is provided on a surface of the dielectric except for a region facing the substrate. The mounting includes selecting a combination of a first length from the first end to the second end of the third wiring of the skew adjustment element in the first wiring portion and a second length from the first end to the second end of the third wiring of the skew adjustment element in the second wiring portion such that a skew between the first signal transmitted through the first wiring portion provided with the skew adjustment element and the second signal transmitted through the second wiring portion provided with the skew adjustment element is smaller than the skew measured in the measuring.

In the manufacturing method according to [6], in the mounting, the combination of the length from the first end to the second end of the third wiring of the skew adjustment element in the first wiring portion (first length) and the length from the first end to the second end of the third wiring of the skew adjustment element in the second wiring portion (second length) is selected. In this case, the combination of the first length and the second length is selected such that the skew between the first signal transmitted through the first wiring portion provided with the skew adjustment element and the second signal transmitted through the second wiring portion provided with the skew adjustment element is smaller than the skew measured in the measuring. Thus, according to the method of manufacturing a wiring module of the above [6], it is possible to reduce the skew of the differential signal.

[7] A method of manufacturing a wiring module according to an embodiment of the present disclosure includes preparing a first wiring portion and a second wiring portion respectively transmitting a first signal and a second signal constituting a differential signal, each of the first wiring portion and the second wiring portion having a first wiring and a second wiring provided on a substrate; measuring a skew between the first signal and the second signal; and in each of the first wiring portion and the second wiring portion, mounting a skew adjustment element including a third wiring having a first end and a second end by disposing the skew adjustment element on the substrate and conductively bonding the first end and the second end respectively to the first wiring and the second wiring. In at least one of the first wiring portion or the second wiring portion, the skew adjustment element further includes a dielectric, and the third wiring is provided on a surface of the dielectric except for a region facing the substrate. The mounting includes selecting a combination of a first dielectric constant of the dielectric of the skew adjustment element in the first wiring portion and a second dielectric constant of the dielectric of the skew adjustment element in the second wiring portion such that a skew between the first signal transmitted through the first wiring portion provided with the skew adjustment element and the second signal transmitted through the second wiring portion provided with the skew adjustment element is smaller than the skew measured in the measuring.

In the method of manufacturing according to [7], in the mounting, the combination of the dielectric constant of the dielectric of the skew adjustment element in the first wiring portion (first dielectric constant) and the dielectric constant of the dielectric of the skew adjustment element in the second wiring portion (second dielectric constant) is selected. In this case, the combination of the first dielectric constant and the second dielectric constant is selected such that the skew between the first signal transmitted through the first wiring portion provided with the skew adjustment element and the second signal transmitted through the second wiring portion provided with the skew adjustment element is smaller than the skew measured in the measuring. This is because the propagation speed of a signal transmitted through the third wiring varies depending on the dielectric constant of the dielectric adjacent to the third wiring. Thus, according to the method of manufacturing a wiring module of the above [7], it is possible to reduce the skew of the differential signal.

### Details of Embodiments of Present Disclosure

Specific examples of a wiring module and a method of manufacturing the wiring module of the present disclosure will be described below with reference to the drawings. The present invention is not limited to these examples, but is defined by the scope of the claims, and is intended to include all modifications within the meaning and scope equivalent to the scope of the claims. In the following description, the same elements are denoted by the same reference numerals in the description of the drawings, and redundant description will be omitted.

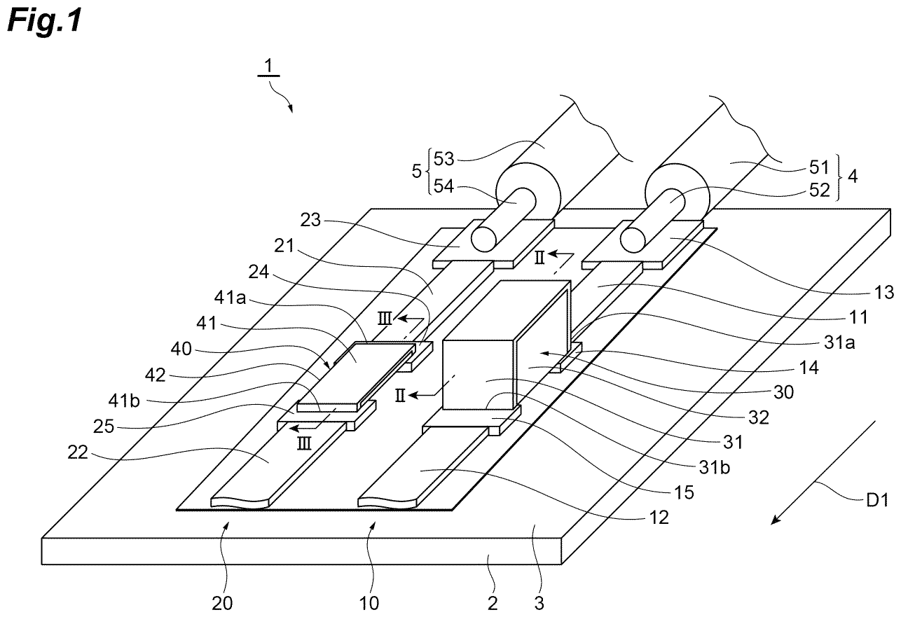

FIG. 1 is a perspective view showing a wiring module 1 according to an embodiment of the present disclosure. In the embodiment, wiring module 1 is, for example, a paddle card built in a connector. Wiring module 1 includes a substrate 2, a first wiring portion 10, and a second wiring portion 20. Substrate 2 is an insulating flat plate and has a flat main surface 3. First wiring portion 10 and second wiring portion 20 are provided on main surface 3 of substrate 2. First wiring portion 10 and second wiring portion 20 extend along a direction D1. First wiring portion 10 and second wiring portion 20 are arranged in parallel to each other in a direction intersecting with direction D1. First wiring portion 10 and second wiring portion 20 respectively transmit a first signal and a second signal constituting a differential signal.

First wiring portion 10 includes a first wiring 11, a second wiring 12, and a skew adjustment element 30. First wiring 11 and second wiring 12 are provided on main surface 3 of substrate 2 so as to be arranged on the same straight line along direction D1. First wiring 11 and second wiring 12 has a film shape.

First wiring 11 includes a pad 13 and a pad 14. Second wiring 12 includes a pad 15. Pad 13 is located at the first end of first wiring 11, and pad 14 is located at the second end of first wiring 11. Pad 15 is located at the first end of second wiring 12. Pad 14 is arranged with pad 15 in direction D1. A cable 4 is connected to pad 13. Cable 4 has a resin coating 51 and a signal wire 52. Signal wire 52 has a linear shape with a circular cross section, and is conductively bonded to pad 13 by means of a conductive adhesive. Resin coating 51 covers the outer periphery of signal wire 52 so as to cover signal wire 52. The second end of second wiring 12 is connected to an output part of wiring module 1, and is connected to an external element such as a receiver.

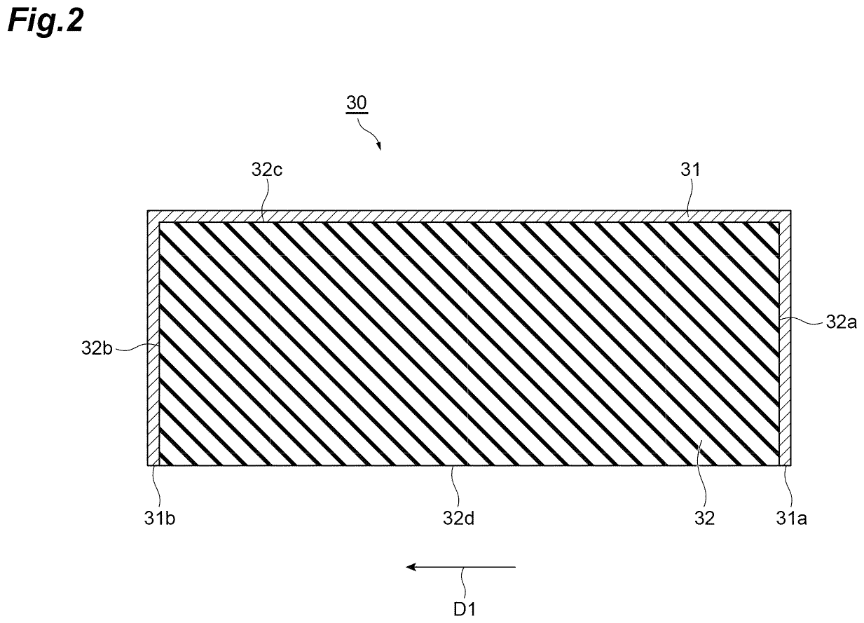

Skew adjustment element 30 is interposed between pad 14 and pad 15 in first wiring portion 10, and electrically connects pad 14 to pad 15. FIG. 2 is a cross-sectional view taken along line II-II shown in FIG. 1, showing a cross section of skew adjustment element 30 along direction D1. As shown in FIGS. 1 and 2, skew adjustment element 30 has a third wiring 31 and a dielectric 32.

Dielectric 32 has a rectangular parallelepiped shape elongated in direction D1. Dielectric 32 has a flat first end face 32a and a flat second end face 32b with direction D1 as a normal direction. First end face 32a and second end face 32b face away from each other in direction D1. First end face 32a of dielectric 32 is located on pad 14, and second end face 32b of dielectric 32 is located on pad 15. Dielectric 32 further has a flat upper surface 32c and a flat lower surface 32d which face in a direction intersecting with main surface 3. Upper surface 32c and lower surface 32d face away from each other. Lower surface 32d faces main surface 3. Upper surface 32c faces the same direction as main surface 3, for example.

Third wiring 31 is provided on a surface of dielectric 32 except for a region (that is, lower surface 32d) facing substrate 2, and adheres to the surface. In the illustrated example, third wiring 31 is provided on first end face 32a, second end face 32b, and upper surface 32c of dielectric 32, and is not provided on the side surface of dielectric 32. Third wiring 31 has a first end 31a and a second end 31b. First end 31a and second end 31b are formed so as to be flush with lower surface 32d of dielectric 32. As shown in FIG. 1, first end 31a of third wiring 31 is conductively bonded to pad 14, and second end 31b of third wiring 31 is conductively bonded to pad 15. Third wiring 31 is formed on the surface of dielectric 32 by plating, for example.

Second wiring portion 20 includes a first wiring 21, a second wiring 22, and a skew adjustment element 40. First wiring 21 and second wiring 22 are provided on main surface 3 of substrate 2 so as to be arranged on the same straight line along direction D1. First wiring 21 and second wiring 22 has a film shape.

First wiring 21 includes a pad 23 and a pad 24. Second wiring 22 includes a pad 25. Pad 23 is located at the first end of first wiring 21, and pad 24 is located at the second end of first wiring 21. Pad 25 is located at the first end of second wiring 22. Pad 24 is arranged with pad 25 in direction D1. A cable 5 is connected to pad 23. Cable 5 has a resin coating 53 and a signal wire 54. Signal wire 54 has a linear shape with a circular cross section, and is conductively bonded to pad 23 by means of a conductive adhesive. Resin coating 53 covers the outer periphery of signal wire 54 so as to cover signal wire 54. The second end of second wiring 22 is connected to an output part of wiring module 1, and is connected to an external element such as a receiver.

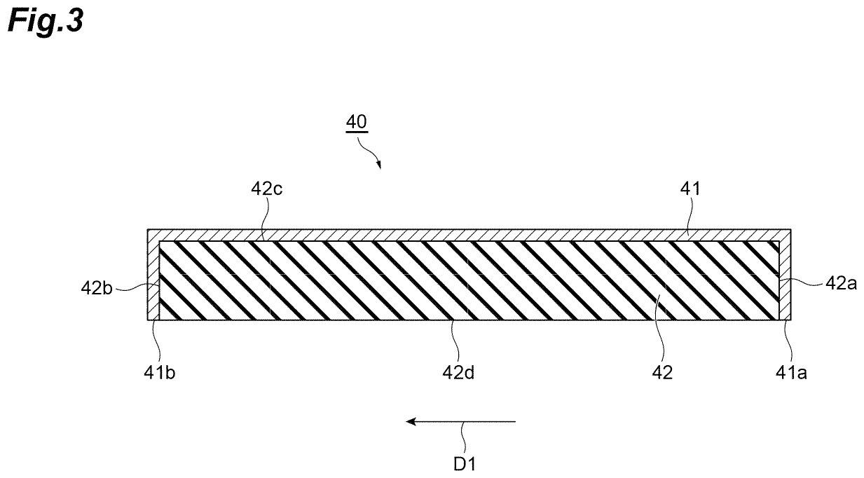

Skew adjustment element 40 is interposed between pad 24 and pad 25 in second wiring portion 20, and electrically connects pad 24 to pad 25. FIG. 3 is a cross-sectional view taken along line III-III shown in FIG. 1, showing a cross section of skew adjustment element 40 along direction D1. As shown in FIGS. 1 and 2, skew adjustment element 40 has a third wiring 41 and a dielectric 42.

In the embodiment, the dielectric constant of dielectric 42 is equal to the dielectric constant of dielectric 32 of skew adjustment element 30. Dielectric 42 has a rectangular parallelepiped shape elongated in direction D1. Dielectric 42 has a flat first end face 42a and a flat second end face 42b with direction DI as a normal direction. First end face 42a and second end face 42b face away from each other in direction D1. First end face 42a of dielectric 42 is located on pad 24, and second end face 42b of dielectric 42 is located on pad 25. Dielectric 42 further has a flat upper surface 42c and a flat lower surface 42d which face in a direction intersecting with main surface 3. Upper surface 42c and lower surface 42d face away from each other. Lower surface 42d faces main surface 3. Upper surface 42c faces the same direction as main surface 3, for example.

Third wiring 41 is provided on a surface of dielectric 42 except for a region (that is, lower surface 42d) facing substrate 2, and adheres to the surface. In the illustrated example, third wiring 41 is provided on first end face 42a, second end face 42b, and upper surface 42c of dielectric 42, and is not provided on the side surface of dielectric 42. Third wiring 41 has a first end 41a and a second end 41b. First end 41a and second end 41b are formed to be flush with lower surface 42d of dielectric 42. As shown in FIG. 1, first end 41a of third wiring 41 is conductively bonded to pad 24, and second end 41b of third wiring 41 is conductively bonded to pad 25. Third wiring 41 is formed on the surface of dielectric 42 by plating, for example.

The material of pads 13 to 15 and pads 23 to 25 is a metal such as copper (Cu). The material of the portion of first wiring 11 except for pads 13 and 14, the portion of second wiring 12 except for pad 15, the portion of first wiring 21 except for pads 23 and 24, and the portion of second wiring 22 except for pad 25 is a metal such as copper. The material of dielectric 32 and dielectric 42 is, for example, ceramic or glass epoxy, and may include both ceramic and glass epoxy. The material of third wiring 31 and third wiring 41 is, for example, a metal including at least one of gold (Au), silver (Ag), copper, tin (Sn), nickel (Ni), and chromium (Cr).

The thickness of dielectric 32 in the direction intersecting with main surface 3 is larger than the thickness of dielectric 42 in the same direction. In other words, the lengths of first end face 32a and second end face 32b in the direction intersecting with main surface 3 are longer than the lengths of first end face 42a and second end face 42b in the same direction. Thus, the length from first end 31a to second end 31b of third wiring 31 of skew adjustment element 30 (first length) is longer than the length from first end 41a to second end 41b of third wiring 41 of skew adjustment element 40 (second length). As described above, in the embodiment, the length of third wiring 31 and the length of third wiring 41 are different from each other. The thickness of dielectric 32, 42 is, for example, 0.1 mm to 3 mm. The length from first end 31a to second end 31b of third wiring 31 and the length from first end 41a to second end 41b of third wiring 41 are, for example, 0.3 mm to 5 mm.

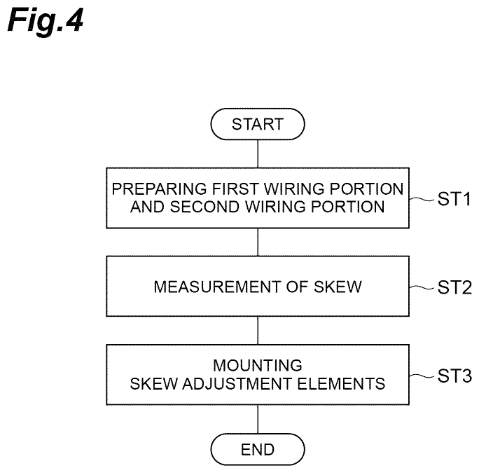

FIG. 4 is a flowchart showing a method of manufacturing wiring module 1. The manufacturing method includes a step ST1 of preparing first wiring portion 10 and second wiring portion 20, a step ST2 of measuring a skew, and a step ST3 of mounting.

In step ST1, first, substrate 2 is prepared in which first wiring 11 and second wiring 12 of first wiring portion 10 and first wiring 21 and second wiring 22 of second wiring portion 20 are formed on main surface 3. Then, signal wire 52 of cable 4 is conductively bonded to pad 13 of first wiring 11, and signal wire 54 of cable 5 is conductively bonded to pad 23 of first wiring 21.

In step ST2, a skew between a first signal transmitted from signal wire 52 of cable 4 to first wiring 11 and a second signal transmitted from signal wire 54 of cable 5 to first wiring 21 is measured. Note that, before signal wire 52, 54 is conductively bonded to pad 13, 23, the skew between the first signal transmitted through signal wire 52 and the second signal transmitted through signal wire 54 may be measured.

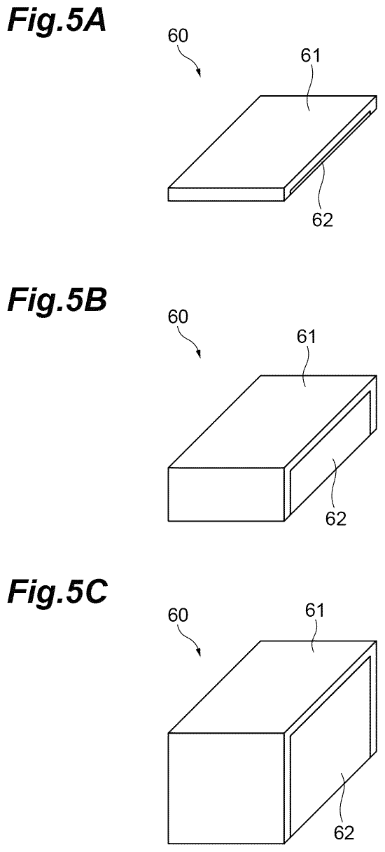

In step ST3, first, a plurality of skew adjustment elements having different third wiring lengths are prepared. FIGS. 5A, 5B, and 5C are perspective views showing examples of a plurality of skew adjustment elements 60. These skew adjustment elements 60 have a third wiring 61 and a dielectric 62. Third wiring 61 corresponds to third wiring 31, 41 of skew adjustment element 30, 40. Dielectric 62 corresponds to dielectric 32, 42 of skew adjustment element 30, 40. These skew adjustment elements 60 are different from each other in the thickness of dielectric 62, and as a result, these skew adjustment elements 60 are different from each other in the length of third wiring 61. The thickness of dielectric 62 of skew adjustment element 60 shown in FIG. 5A is the smallest, and as a result, the length of third wiring 61 of skew adjustment element 60 shown in FIG. 5A is the shortest. In addition, the thickness of dielectric 62 of skew adjustment element 60 shown in FIG. 5C is the largest, and as a result, the length of third wiring 61 of skew adjustment element 60 shown in FIG. 5C is the longest.

In step ST3, a combination of the length (first length) from first end 31a to second end 31b of third wiring 31 of skew adjustment element 30 and the length (second length) from first end 41a to second end 41b of third wiring 41 of skew adjustment element 40 is selected from the plurality of skew adjustment elements 60 based on the value of the skew measured in step ST2. That is, the lengths of third wiring 31 and third wiring 41 are selected so that the skew between the first signal transmitted through first wiring portion 10 provided with skew adjustment element 30 and the second signal transmitted through second wiring portion 20 provided with skew adjustment element 40 is smaller than the skew measured in step ST2. For example, skew adjustment elements 60 to be used as skew adjustment element 30 and skew adjustment element 40 are selected from the plurality of skew adjustment elements 60 so that the difference between the signal propagation length of third wiring 31 and the signal propagation length of third wiring 41 is closest to the signal propagation length corresponding to the skew measured in step ST2. In the illustrated example, third wiring 31 is longer than third wiring 41, but third wiring 41 may be longer than third wiring 31 depending on the value of the skew measured in step ST2.

In step ST3, subsequently, skew adjustment element 30 and skew adjustment element 40 are arranged at predetermined positions on main surface 3 of substrate 2. Then, first end 31a of third wiring 31 of skew adjustment element 30 is conductively bonded to first wiring 11, and second end 31b of third wiring 31 of skew adjustment element 30 is conductively bonded to second wiring 12. Similarly, first end 41a of third wiring 41 of skew adjustment element 40 is conductively bonded to first wiring 21, and second end 41b of third wiring 41 of skew adjustment element 40 is conductively bonded to second wiring 22.

The effects obtained by wiring module 1 and the method of manufacturing wiring module 1 of the embodiment described above will be described. In wiring module 1 of the embodiment, the length of third wiring 31 of skew adjustment element 30 in first wiring portion 10 (first length) is different from the length of third wiring 41 of skew adjustment element 40 in second wiring portion 20 (second length). In this case, by selecting a combination of the first length and the second length, it is possible to make the skew between the first signal after being transmitted through first wiring portion 10 and the second signal after being transmitted through second wiring portion 20 smaller than the skew between the first signal before being transmitted through first wiring portion 10 and the second signal before being transmitted through second wiring portion 20. Thus, according to wiring module 1 of the embodiment, it is possible to reduce the skew of the differential signal.

As in the embodiment, skew adjustment element 30, 40 of both first wiring portion 10 and second wiring portion 20 may include a dielectric (dielectric 32, 42). In addition, dielectric 32 of skew adjustment element 30 in first wiring portion 10 may have a thickness different from a thickness of dielectric 42 of skew adjustment element 40 in second wiring portion 20, and thereby the first length may be different from the second length. With such a configuration of skew adjustment element 30, 40, it is possible to realize an aspect in which the first length is different from the second length with a simple structure.

As in the embodiment, third wiring 31, 41 of skew adjustment element 30, 40 of first wiring portion 10 and second wiring portion 20 may include at least one metal of tin, nickel, and chromium. In this case, third wiring 31, 41 can be formed, for example by plating, which adheres strongly to the surface of dielectric 32, 42.

In the method of manufacturing wiring module 1 of the embodiment, in step ST3, a combination of the first length and the second length is selected. At this time, the combination of the first length and the second length is selected so that the skew between the first signal transmitted through first wiring portion 10 provided with skew adjustment element 30 and the second signal transmitted through second wiring portion 20 provided with skew adjustment element 40 is smaller than the skew measured in step ST2. Thus, according to the manufacturing method of the embodiment, the skew of the differential signal can be reduced.

### Modification

In the above embodiment, the dielectric constant of dielectric 32 of skew adjustment element 30 and the dielectric constant of dielectric 42 of skew adjustment element 40 are equal to each other, but the dielectric constant of dielectric 32 (first dielectric constant) and the dielectric constant of dielectric 42 (second dielectric constant) may be different from each other. The propagation speed of the first signal transmitted through third wiring 31 varies depending on the dielectric constant of dielectric 32 adjacent to third wiring 31. Similarly, the propagation speed of the second signal transmitted through third wiring 41 varies depending on the dielectric constant of dielectric 42 adjacent to third wiring 41. Thus, the dielectric constant of dielectric 32 and the dielectric constant of dielectric 42 is different from each other, and as a result, the skew between the first signal and the second signal can be reduced. The dielectric constant of dielectric 32, 42 is, for example, 1.5 to 10. In this modification, the thickness of dielectric 32 and the thickness of dielectric 42 may be equal to each other, and the first length of third wiring 31 and the second length of third wiring 41 may be equal to each other.

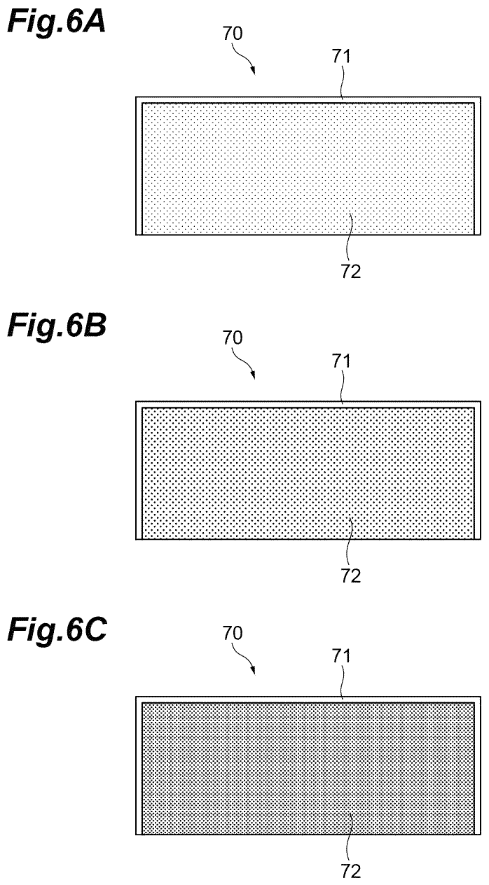

In this modification, in step ST3 of the above-described embodiment, a plurality of skew adjustment elements having different dielectric constants of the dielectric are prepared instead of the plurality of skew adjustment elements having different third wiring lengths. FIGS. 6A, 6B and 6C are side views showing examples of a plurality of skew adjustment elements 70. These skew adjustment elements 70 have a third wiring 71 and a dielectric 72. Third wiring 71 corresponds to third wiring 31, 41 of skew adjustment element 30, 40. Dielectric 72 corresponds to dielectric 32, 42 of skew adjustment element 30, 40. These skew adjustment elements 70 are different from each other in the dielectric constant of dielectric 72. In the figure, the dielectric constant of dielectric 72 is shown by the shade of color. The dielectric constant of dielectric 62 of skew adjustment element 60 shown in FIG. 6A is the smallest, and the dielectric constant of dielectric 62 of skew adjustment element 60 shown in FIG. 6C is the largest.

In the wiring module of the modification, by selecting a combination of the dielectric constant of dielectric 32 and the dielectric constant of dielectric 42, it is possible to make the skew between the first signal after being transmitted through first wiring portion 10 and the second signal after being transmitted through second wiring portion 20 smaller than the skew between the first signal before being transmitted through first wiring portion 10 and the second signal before being transmitted through second wiring portion 20. Thus, according to the wiring module of the modification, the skew of the differential signal can be reduced.

In the method of manufacturing the wiring module of the modification, a combination of the dielectric constant of dielectric 32 and the dielectric constant of dielectric 42 is selected in step ST3. At this time, the combination of the dielectric constant of dielectric 32 and the dielectric constant of dielectric 42 is selected so that the skew between the first signal transmitted through first wiring portion 10 provided with skew adjustment element 30 and the second signal transmitted through second wiring portion 20 provided with skew adjustment element 40 is smaller than the skew measured in step ST2. Thus, according to the manufacturing method of the modification, the skew of the differential signal can be reduced.

Although the present invention has been described in detail based on the embodiments and modifications, the present invention is not limited to the embodiments and modifications described above, and can be modified without departing from the scope of the invention. For example, the shape of dielectric 32 and dielectric 42 is not limited to a rectangular parallelepiped as in the above embodiment, and may be a cube or a frustum, or may be a shape partially including a curved surface, such as a semi-cylinder. In the above-described embodiment, both skew adjustment element 30 and skew adjustment element 40 have a dielectric, but only one of skew adjustment element 30 and skew adjustment element 40 may have a dielectric.

In the above embodiment, third wiring 31, 41 is not provided on the side surface of dielectric 32, 42, but third wiring 31, 41 may be further provided on the side surface of dielectric 32, 42. In this case, third wiring 31, 41 may be provided only in a region of the side surface of dielectric 32, 42, the region being away from substrate 2.

What is claimed is:

1. A wiring module comprising:
a substrate; and
a first wiring portion and a second wiring portion respectively transmitting a first signal and a second signal constituting a differential signal,
wherein each of the first wiring portion and the second wiring portion includes a first wiring provided on the substrate, a second wiring provided on the substrate, and a skew adjustment element mounted on the substrate and including a third wiring,
the third wiring has a first end conductively bonded to the first wiring and a second end conductively bonded to the second wiring,
in at least one of the first wiring portion or the second wiring portion, the skew adjustment element further includes a dielectric, and the third wiring is provided on a surface of the dielectric except for a region facing the substrate, and
a first length from the first end to the second end of the third wiring of the skew adjustment element in the first wiring portion is different from a second length from the first end to the second end of the third wiring of the skew adjustment element in the second wiring portion.

2. The wiring module according to claim 1,
wherein the skew adjustment element in each of the first wiring portion and the second wiring portion includes the dielectric, and
the dielectric of the skew adjustment element in the first wiring portion has a thickness different from a thickness of the dielectric of the skew adjustment element in the second wiring portion, and the first length is different from the second length.

3. A wiring module comprising:
a substrate; and
a first wiring portion and a second wiring portion respectively transmitting a first signal and a second signal constituting a differential signal,
wherein each of the first wiring portion and the second wiring portion includes a first wiring provided on the substrate, a second wiring provided on the substrate, and a skew adjustment element mounted on the substrate and including a third wiring,
the third wiring has a first end conductively bonded to the first wiring and a second end conductively bonded to the second wiring,
in each of the first wiring portion and the second wiring portion, the skew adjustment element further includes a dielectric, and the third wiring is provided on a surface of the dielectric except for a region facing the substrate, and
a first dielectric constant of the dielectric of the skew adjustment element in the first wiring portion is different from a second dielectric constant of the dielectric of the skew adjustment element in the second wiring portion.

4. The wiring module according to claim 3, wherein the dielectric of the skew adjustment element in each of the first wiring portion and the second wiring portion includes at least one of ceramic or glass epoxy.

5. The wiring module according to claim 1, wherein the third wiring of the skew adjustment element in each of the first wiring portion and the second wiring portion includes at least one metal of gold, silver, copper, tin, nickel, or chromium.

6. The wiring module according to claim 3, wherein the third wiring of the skew adjustment element in each of the first wiring portion and the second wiring portion includes at least one metal of gold, silver, copper, tin, nickel, or chromium.

7. A method of manufacturing a wiring module, the method comprising:
preparing a first wiring portion and a second wiring portion respectively transmitting a first signal and a second signal constituting a differential signal, each of the first wiring portion and the second wiring portion having a first wiring and a second wiring provided on a substrate;
measuring a skew between the first signal and the second signal; and
in each of the first wiring portion and the second wiring portion, mounting a skew adjustment element including a third wiring having a first end and a second end by disposing the skew adjustment element on the substrate and conductively bonding the first end and the second end respectively to the first wiring and the second wiring,
wherein in at least one of the first wiring portion or the second wiring portion, the skew adjustment element further includes a dielectric, and the third wiring is provided on a surface of the dielectric except for a region facing the substrate, and
the mounting includes selecting a combination of a first length from the first end to the second end of the third wiring of the skew adjustment element in the first wiring portion and a second length from the first end to the second end of the third wiring of the skew adjustment element in the second wiring portion such that a skew between the first signal transmitted through the first wiring portion provided with the skew adjustment element and the second signal transmitted through the second wiring portion provided with the skew adjustment element is smaller than the skew measured in the measuring.

8. A method of manufacturing a wiring module, the method comprising:
preparing a first wiring portion and a second wiring portion respectively transmitting a first signal and a second signal constituting a differential signal, each of the first wiring portion and the second wiring portion having a first wiring and a second wiring provided on a substrate;
measuring a skew between the first signal and the second signal; and
in each of the first wiring portion and the second wiring portion, mounting a skew adjustment element including a third wiring having a first end and a second end by disposing the skew adjustment element on the substrate and conductively bonding the first end and the second end respectively to the first wiring and the second wiring,
wherein in at least one of the first wiring portion or the second wiring portion, the skew adjustment element further includes a dielectric, and the third wiring is provided on a surface of the dielectric except for a region facing the substrate, and
the mounting includes selecting a combination of a first dielectric constant of the dielectric of the skew adjustment element in the first wiring portion and a second dielectric constant of the dielectric of the skew adjustment element in the second wiring portion such that a skew between the first signal transmitted through the first wiring portion provided with the skew adjustment element and the second signal transmitted through the second wiring portion provided with the skew adjustment element is smaller than the skew measured in the measuring.
